(19) United States
(12) Patent Application Publication
(10) Pub. No.: US 2015/0179943 A1
(43) Pub. Date: Jun. 25, 2015

(54) ORGANIC ELECTROLUMINESCENCE DEVICE

(71) Applicant: SAMSUNG DISPLAY CO., LTD., Yongin-City (KR)

(72) Inventor: Shuri SATO, Yokohama (JP)

(21) Appl. No.: 14/581,028

(22) Filed: Dec. 23, 2014

(30) Foreign Application Priority Data
Dec. 25, 2013 (JP) 2013-266552

(51) Int. Cl. H01L 51/00; H01L 51/52; H01L 51/50

(52) U.S. Cl. CPC H01L 51/006; H01L 51/5064; H01L 51/5012; H01L 51/5221; H01L 51/0072; H01L 51/0061; H01L 51/0052

(57) ABSTRACT

An organic electroluminescence device includes an anode, a hole transport layer on the anode, the hole transport layer including a plurality of layers having different compounds as main components, an emission layer on the hole transport layer, and a cathode on the emission layer. A hole mobility of a first layer of the hole transport layer having the greatest thickness among the plurality of layers of the hole transport layer is greater than a hole mobility of at least one layer of the hole transport layer between the first layer of the hole transport layer and the emission layer.

### CROSS-REFERENCE TO RELATED APPLICATION

Japanese Patent Application No. 2013-266552, filed on Dec. 25, 2013, in the Japanese Patent Office, and entitled: “Organic Electroluminescence Device,” is incorporated by reference herein in its entirety.

### BACKGROUND

1. Field

Embodiments relate to an organic electroluminescence device.

2. Description of the Related Art

In recent years, organic electroluminescence (EL) displays have been actively developed. Unlike a liquid crystal display or the like, the organic EL display is a self-luminescent display in which holes and electrons injected from an anode and a cathode are recombined in an emission layer to emit light from a light-emitting material including an organic compound, thereby providing a display.

An organic electroluminescence device (hereinafter referred to as an organic EL device) may include a plurality of layers having different properties such as an emission layer and a layer for transporting holes or electrons as carriers to the emission layer.

### SUMMARY

Embodiments are directed to an organic electroluminescence (EL) device including an anode, a hole transport layer on the anode, the hole transport layer including a plurality of layers having different compounds as main components, an emission layer on the hole transport layer, and a cathode on the emission layer. A hole mobility of a first layer of the hole transport layer having the greatest thickness among the plurality of layers of the hole transport layer is greater than a hole mobility of at least one layer of the hole transport layer between the first layer of the hole transport layer and the emission layer.

The hole mobility of the first layer of the hole transport layer in an electric field range from about 0.3 to about 1.0 MV/cm may be from about 1×10⁻⁴ to about 1×10⁻³ cm²/V·sec. The hole mobility of the at least one layer of the hole transport layer between the first layer of the hole transport layer and the emission layer in an electric field range from about 0.3 to about 1.0 MV/cm may be from about 1×10⁻⁵ to about 1×10⁻⁴ cm²/V·sec.

A thickness of the at least one layer of the hole transport layer between the first layer of the hole transport layer and the emission layer may be less than 1/10 of a thickness of the first hole transport layer.

A main component of the at least one layer of the hole transport layer between the first layer of the hole transport layer and the emission layer may be an aminocarbazole derivative.

The aminocarbazole derivative may be a compound represented by the following Formula (1a) or (1b):

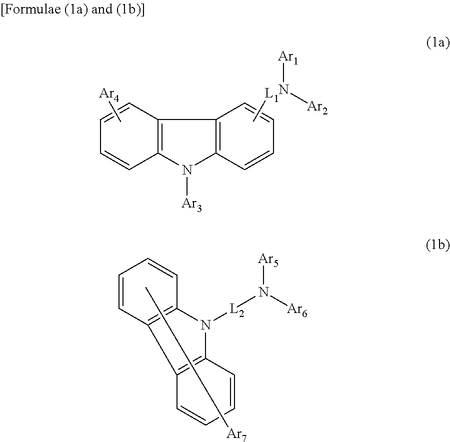

In Formula 1(a), Ar₁ to Ar₄ are a substituted or unsubstituted aryl group, or a substituted or unsubstituted heteroaryl group, and L₁ is a connecting group, a substituted or unsubstituted arylene group, or a substituted or unsubstituted heteroarylene group.

In Formula 1(b), Ar₅ to Ar₇ are a substituted or unsubstituted aryl group, or a substituted or unsubstituted heteroaryl group, and L₂ is a connecting group, a substituted or unsubstituted arylene group, or a substituted or unsubstituted heteroarylene group.

A main component of the at least one layer of the hole transport layer between the first layer of the hole transport layer and the emission layer may be a monoamine derivative. The monoamine derivative may be a compound represented by the following Formula (2):

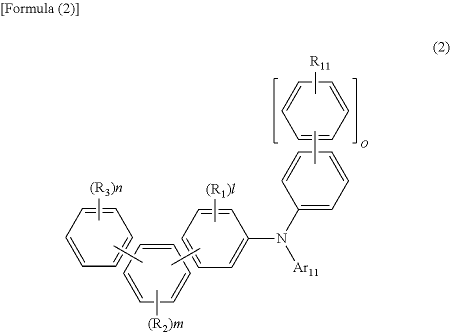

In Formula (2), R₁, R₂ and R₃ are independently a hydrogen atom, a halogen atom, a substituted or unsubstituted alkyl group having 1 to 15 carbon atoms, a substituted or unsubstituted aryl group having 6 to 30 carbon atoms, or a substituted or unsubstituted heteroaryl group having 1 to 30 carbon atoms,

each of l, m and n is an integer satisfying 0≦l≦4, 0≦m≦4, and 0≦n≦5,

Ar₁₁ is a substituted or unsubstituted aryl group having 6 to 30 carbon atoms,

R₁₁ is a hydrogen atom, a fluorine atom, or a substituted silyl group, and

o is an integer satisfying 0≦o≦3,

where in the case that o is greater than or equal to 2, R₁₁ may be different from each other among the above-described substituents.

A main component of the at least one layer of the hole transport layer between the first layer of the hole transport layer and the emission layer may be a carbazole derivative. The carbazole derivative may be a compound represented by the following Formula (3):

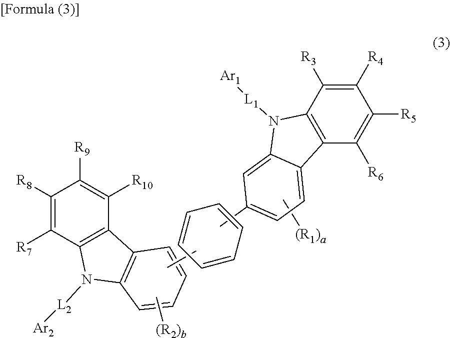

In Formula (3), Ar₁ is a substituted or unsubstituted aryl group having 6 to 30 carbon atoms, a substituted or unsubstituted heteroaryl group having 1 to 30 carbon atoms, or a substituted or unsubstituted alkyl group having 1 to 15 carbon atoms,

R₁ to R₁₀ are independently a substituted or unsubstituted aryl group having 6 to 30 carbon atoms, a substituted or unsubstituted heteroaryl group having 1 to 30 carbon atoms, a substituted or unsubstituted alkyl group having 1 to 15 carbon atoms, a substituted or unsubstituted alkoxy group, a halogen atom, a hydrogen atom, or a deuterium atom,

Ar₂ is a substituted or unsubstituted condensed ring having 6 to 30 carbon atoms and optionally including a heteroatom selected from the group of nitrogen, oxygen, sulfur, phosphorus and silicon, or a substituted or unsubstituted condensed ring including carbon and nitrogen,

Ar₁ and Ar₂ are different substituents from each other,

a and b are 0 to 3,

L₁ and L₂ are a single bond, or a divalent connecting group, and

a plurality of adjacent R₁ to R₁₀ may combine and form an unsaturated ring, where R₁ and R₆, or R₂ and R₁₀ are combined, and an aromatic ring is not formed.

The emission layer may include a blue fluorescent emitting material.

The emission layer may include a red phosphorescent emitting material.

The emission layer may include a green phosphorescent emitting material.

### BRIEF DESCRIPTION OF THE DRAWINGS

Features will become apparent to those of skill in the art by describing in detail exemplary embodiments with reference to the attached drawings in which:

FIG. 1 illustrates a schematic diagram depicting an embodiment of an organic EL device;

FIG. 2 illustrates a schematic cross-sectional view of an embodiment of a hole transport layer provided in an organic EL device according to an embodiment; and

FIG. 3 illustrates a schematic cross-sectional view of an organic EL device manufactured by using a material for an organic EL device.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

[With Respect to the Configuration of Organic EL Device]

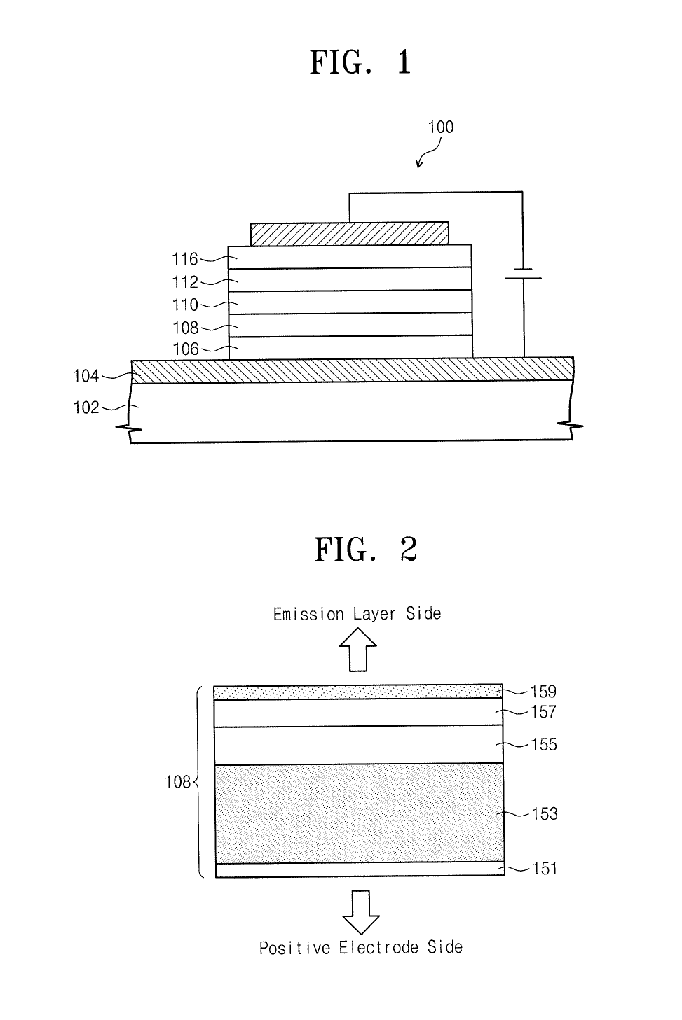

First, referring to FIGS. 1 and 2, the configuration of an organic EL device according to an embodiment will be explained in detail. FIG. 1 illustrates a schematic cross-sectional view depicting an embodiment of an organic EL device, and FIG. 2 illustrates a schematic cross-sectional view of an embodiment of a hole transport layer provided in an organic EL device according to an embodiment.

The organic EL device according to an embodiment may have the structure illustrated in FIG. 1, as an example.

[With Respect to the Entire Configuration of Organic EL Device]

The organic EL device 100 according to an embodiment includes a substrate 102, a first electrode 104 disposed on the substrate 102, a hole injection layer 106 disposed on the first electrode 104, a hole transport layer 108 disposed on the hole injection layer 106, an emission layer 110 disposed on the hole transport layer 108, an electron transport layer 112 disposed on the emission layer 110, an electron injection layer 114 disposed on the electron transport layer 112 and a second electrode 116, as illustrated in FIG. 1.

The substrate 102 may be a suitable substrate used in an organic EL device. For example, the substrate 102 may be a glass substrate, a semiconductor substrate, or a transparent plastic substrate.

The first electrode 104 may be an anode. The first electrode 104 may be formed by a deposition method, a sputtering method or a coating method on the substrate 102. For example, the first electrode 104 may be formed as a transparent electrode including a metal, an alloy, a conductive compound, etc. having high work function. The first electrode 104 may include indium tin oxide (ITO), indium zinc oxide (IZO), tin oxide (SnO₂), zinc oxide (ZnO), etc., which are transparent and have good conductivity. In some implementations, the first electrode 104 may be formed as a reflection type electrode including magnesium (Mg), aluminum (Al), etc.

The hole injection layer 106 is a layer that facilitates the injection of holes from the first electrode 104. The hole injection layer 106 may be formed on the first electrode 104. In some implementations, the hole injection layer 106 may be omitted. The hole injection layer 106 may be formed on the first electrode 104 by a vacuum deposition method, a spin coating method, an inkjet method, etc. The hole injection layer 106 may be formed to a thickness from about 0.1 nm to about 1,000 nm, or, for example, from about 1 nm to about 100 nm.

The hole injection layer 106 may include, for example, N,N′-diphenyl-N,N′-bis-[4-(phenyl-m-tolyl-amino)-phenyl]-biphenyl-4,4′-diamine (DNTPD), a phthalocyanine compound such as copper phthalocyanine, 4,4′,4″-tris(3-methylphenylamino)triphenylamine (m-MTDATA), N,N′-di(1-naphthyl)-N,N′-diphenylbenzidine (NPB), 4,4′,4″-tris{N,N-diamino}triphenylamine (TDATA), 4,4′,4″-tris(N,N-2-naphthylamino)triphenylamine (2-TNATA), polyaniline/dodecylbenzenesulfonic acid (Pani/DBSA), poly(3,4-ethylenedioxythiophene)/poly(4-styrenesulfonate) (PEDOT/PSS), polyaniline/camphor sulfonic acid (Pani/CSA), polyaniline/poly(4-styrenesulfonate) (PANI/PSS), or hexaazatriphenylenehexacarbonitrile (HAT(CN)₆, etc.

The hole transport layer 108 is a layer including a hole transport material having hole transporting function. The hole transport layer 108 may not include a host material or an emission dopant as main materials. The hole transport layer 108 according to this embodiment may not itself contributes to the emission luminance of an organic EL device. The hole transport layer 108 may function as an electron inhibiting layer and/or an exciton blocking layer.

The hole transport layer 108 may be formed on the hole injection layer 106 (or on the first electrode 104 if the hole injection layer 106 is omitted) by a vacuum deposition method, a spin coating method, an inkjet method, etc. The organic EL device 100 according to an embodiment may be formed or a plurality of layers including different compounds as main materials, respectively. Detailed configuration of the hole transport layer 108 will be described below.

The emission layer 110 is a layer that emits light by, for example, fluorescence or phosphorescence. The emission layer 110 may be formed on the hole transport layer 108 by a vacuum deposition method, a spin coating method, an inkjet method, etc. The emission layer 110 may include a host material and an emitting dopant material. The emission layer 110 may be formed to a thickness from about 10 nm to about 100 nm, or, for example, from about 20 nm to about 60 nm.

The emission layer 110 may be formed as an emission layer that emits light of specific color. For example, the emission layer 110 may be formed as a red emission layer, a green emission layer or a blue emission layer. In some implementations, the emission layer 110 may be a white emission layer using emitting dopants having a plurality of colors. In addition, the white emission layer may be obtained as a stacked structure of emission layers of different colors.

The host material used in the emission layer 110, may include, for example, tris(8-quinolinolato)aluminum (Alq3), 4,4′,4″-tris(N-carbazolyl)triphenylamine (TCTA), 1,3,5-tris(N-phenylbenzimidazole-2-yl)benzene (TPBI), poly(n-vinylcarbazole) (PVK), 9,10-di(naphthalene-2-yl)anthracene (ADN), 3-tert-butyl-9,10-di(naphth-2-yl)anthracene (TBADN), distyrylarylene (DSA), 4,4′-N,N′-dicarbazole-biphenyl (CBP), or 4,4′-bis(9-carbazole)-2,2′-dimethyl-biphenyl (dmCBP).

A blue dopant used in the emission layer 110, may include, for example, 1,4-bis[2-(3-N-ethylcarbazolyl)vinyl]benzene (BCzVB), a styryl derivative such as 4-(di-p-toluylamino)-4′-[(di-p-toluylamino)styryl]stilbene (DPAVB) or N-(4-((E)-2-(6-((E)-4-(diamino)styryl)naphthalene-2-yl)vinyl)phenyl)-N-phenylbenzeneamine (N-BDAVBi), etc. perylene or a derivative thereof (for example, 2,5,8,11-tetra-t-butylperylene (TBPe)), pyrene or a derivative thereof (for example, 1,1-dipyrene, and 1,4-dipyrenylbenzene), or bis[2-(4,6-difluorophenyl)pyridinate]picolinateiridium(III) (FIrpic), etc.

A red dopant used in the emission layer 110, may include, for example, 5,6,11,12-tetraphenylnaphthacene (rubrene), 4-dicyanomethylene-2-(p-dimethylaminostyryl)-6-methyl-4H-pyrane (DCM) or a derivative thereof, or bis(1-phenylisokinorin)(acetylacetonate)iridium(III) (Ir(piq)₂(acac)), etc.

A green dopant used in the emission layer 110, may include, for example, 3-(2-benzothiazolyl)-7-(diethylamino)coumarin (coumarin 6), tris(2-phenylpyridine)iridium(III) (Ir(ppy)₃), etc.

The electron transport layer 112 is a layer mainly including an electron transport material having electron transporting function. The electron transport layer 112 may be formed on the emission layer 110. In some implementations, the electron transport layer 112 may be omitted. The electron transport layer 112 may function as a hole inhibiting layer and/or an exciton blocking layer. The electron transport layer 112 may be formed by a vacuum deposition method, a spin coating method, an inkjet method, etc. The electron transport layer 112 may be formed to a thickness from about 10 nm to about 100 nm, or, for example, from about 15 nm to about 50 nm. The electron transport layer 112 may include, for example, lithium quinolate (LiQ), lithium fluoride (LiF), etc.

The electron injection layer 114 is a layer facilitating the electron injection from the second electrode 116, The electron injection layer 114 may be formed on the electron transport layer 112 (If the electron transport layer 112 is omitted, the electron injection layer 114 may be formed on the emission layer 110). In some implementations, the electron injection layer may be omitted. The electron injection layer 114 may be formed by using a vacuum deposition method, etc. The electron injection layer 114 may be formed to a thickness from about 0.1 nm to about 10 nm, or, for example, from about 0.1 nm to about 3 nm. The electron injection layer 114 may include, for example, lithium fluoride (LiF), sodium chloride (NaCl), cesium fluoride (CsF), lithium oxide (Li₂O), barium oxide (BaO), etc.

The second electrode 116 may be, for example, a cathode. The second electrode 116 may be formed on the electron injection layer 114 by a deposition method, a sputtering method, etc. The second electrode 116 may be formed as a reflection type electrode including a metal, an alloy, a conductive compound, etc., having low work function. The second electrode 116 may be include, for example, lithium (Li), magnesium (Mg), aluminum (Al), aluminum-lithium (Al—Li), calcium (Ca), magnesium-indium (Mg—In), magnesium-silver (Mg—Ag), etc. In some implementations, the second electrode 116 may be formed as a transparent electrode using indium tin oxide (ITO), indium zinc oxide (IZO), etc.

As described above, the configuration of the organic EL device 100 according to an embodiment has been explained in brief with reference to FIG. 1.

[With Respect to the Configuration of Hole Transport Layer]

Referring to FIG. 2, the configuration of the hole transport layer 108 included in the organic EL device 100 according to an embodiment will be explained in detail hereinafter.

The hole transport layer 108 according to this embodiment includes a plurality of layers, as schematically illustrated in FIG. 2. The plurality of the layers constituting the hole transport layer 108 may include different compounds from each other as main materials, or a portion of the plurality of the layers may include the same compound as main materials. FIG. 2 illustrates five layers, from a hole transport layer 151 at the closest position to the anode to a hole transport layer 159 at the closest position to the emission layer. In other implementations, the number of the layers of the hole transport layer 108 may be different. For example, the number of layers of the hole transport layer 108 may be two or more.

Among the plurality of the layers constituting the hole transport layer 108 according to this embodiment, the thickest layer may be a hole transport layer A as an example of a first hole transport layer. In this case, the hole mobility of the hole transport layer A may be greater than that of at least one layer positioned between the hole transport layer A and the emission layer 110 among the remainder in the hole transport layer 108.

In the hole transport layer 108 composed of five layers as shown in FIG. 2, the thickest layer is a hole transport layer 153. Thus, the hole transport layer 153 may be regarded herein as the hole transport layer A. The hole transport layers positioned between the hole transport layer 153 and the emission layer 110 in FIG. 2 are hole transport layer 155 to hole transport layer 159. According to this embodiment, the hole mobility of the hole transport layer 153 is greater than that of at least one layer of the three hole transport layers 155, 157 and 159.

The hole mobility of the plurality of the layers constituting the hole transport layer 108 may be defined as described above. A thick hole transport layer having high hole mobility may be formed nearer the positive layer (for example, the anode 104) among the layers of the hole transport layer 108 (that is, near an injection side of holes), and a hole transport layer having low hole mobility may be formed nearer the emission layer 110. Due to the thick hole transport layer having high hole mobility, the driving voltage of the organic EL device may be maintained to be low, and a large amount of holes may be injected into the emission layer, thereby attaining the high efficiency of the organic EL device. As described above, in the hole transport layer 108 according to this embodiment, a hole transport material having high hole mobility (for example, having good hole transport capacity) and a hole transport material having relatively low hole mobility (for example, not having good hole transport capacity) may be intentionally provided to attain balance, and the low driving voltage and the high efficiency of an organic EL device may be realized.

Hereinafter, “at least one layer of the hole transport layer 108 positioned between the hole transport layer A and the emission layer 110” will be abbreviated to “a hole transport layer B” for convenience of explanation.

In the case that the hole mobility of the hole transport layer A is from about 1×10⁻⁴ to about 1×10⁻³ cm²/V·sec in an electric field range from about 0.3 to about 1.0 MV/cm, the hole mobility of the hole transport layer B may be from about 1×10⁻⁵ to about 1×10⁴ cm²/V·sec in the electric field range from about 0.3 to about 1.0 MV/cm. By delimiting the hole mobility of the hole transport layer A and the hole transport layer B in the above-described ranges, the driving voltage may be restrained, and emission efficiency may be improved further.

The thickness of the hole transport layer A, may be from about 20 nm to about 300 nm, as an example. If the thickness of the hole transport layer A is greater than about 20 nm, an increase in the probability of generating leakage between an anode and a cathode may be avoided. If the thickness of the hole transport layer A is less than about 300 nm, an undesirable increase in the driving voltage of the organic EL device 100 may be avoided.

The thickness of the hole transport layer B may be less than 1/10 of the thickness of the hole transport layer A, as an example. By controlling the thickness of the hole transport layer B to be less than 1/10 of the hole transport layer A, the formation of a hole transport layer having a relatively small thickness may be possible, and the density of the excitons may be increased by concentrating the holes at the interface of the hole transport layer 108 and the emission layer 110, thereby realizing the high efficiency of a device. In general, the smaller the thickness of the hole transport layer B, the better. In some implementations, the thickness of the hole transport layer B may be greater than or equal to about 25 nm in consideration of layer formation.

In view of the efficient concentration of the holes at the interface of the hole transport layer 108 and the emission layer 110, the hole transport layer B may be a hole transport layer positioned between the hole transport layer A and the emission layer 110. In some implementations, a hole transport layer having relatively lower hole mobility than the hole transport layer B may be provided near the emission layer 110 (for example, at a position of an interface with the emission layer 110). For example, the hole transport layer 159 illustrated in an embodiment in FIG. 2 may be a hole transport layer (that is, the hole transport layer B) formed by using a compound having relatively lower hole mobility than a compound forming the hole transport layer A.

[With Respect to Compounds Forming Hole Transport Layer]

Compounds forming the hole transport layer 108 according to an embodiment will be explained in detail.

In the hole transport layer 108 according to this embodiment, an optional hole transport material may be used as a compound forming the hole transport layer (for example, the hole transport layer 151 in FIG. 2) positioned closer to the anode than the hole transport layer A.

In addition, an optional hole transport material may be used as a hole transport material forming the hole transport layer A (for example, the hole transport layer 153 in FIG. 2). The hole transport material may be a material forming a hole transport layer realizing hole mobility from about 1×10⁻⁴ to about 1×10⁻³ cm²/V·cm in an electric field range from about 0.3 to about 1.0 MV/cm. In this embodiment, the hole mobility as the hole transport layer may be great. The hole mobility as the hole transport layer as described above may be realized through doping into the optional hole transport material.

As the hole transport material forming the hole transport layer B, an optional hole transport material having a relatively smaller hole mobility than the hole transport material forming the hole transport layer A may be used. For example, a hole transport material forming a hole transport layer realizing hole mobility from about 1×10⁻⁵ to about 1×10⁻⁴ cm²/V·cm in an electric field range from about 0.3 to about 1.0 MV/cm may be used.

As the hole transport material forming the hole transport layer B, an aminocarbazole derivative, a monoamine derivative, or a carbazole derivative as shown below may be used.

Particular examples of the aminocarbazole derivative that may form the hole transport layer B may be, for example, compounds illustrated by the following Formula (1a) or (1b).

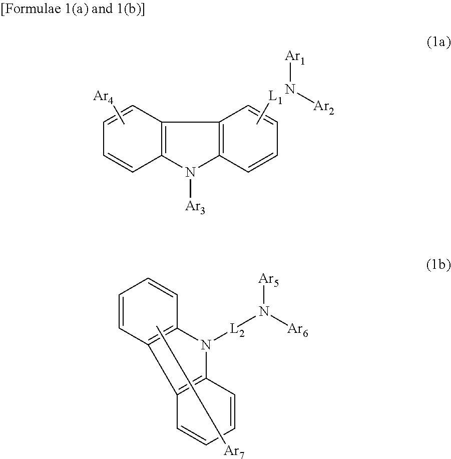

In the above Formula (1a), Ar₁ to Ar₄ are a substituted or unsubstituted aryl group, or a substituted or unsubstituted heteroaryl group, and L₁ is a connecting group, a substituted or unsubstituted arylene group, or a substituted or unsubstituted heteroarylene group. In the above Formula (1b), Ar₅ to Ar₇ are a substituted or unsubstituted aryl group, or a substituted or unsubstituted heteroaryl group, and L₂ is a connecting group, a substituted or unsubstituted arylene group, or a substituted or unsubstituted heteroarylene group.

Particular examples of the monoamine derivative that may form the hole transport layer B include, for example, compounds illustrated by the following Formula (2).

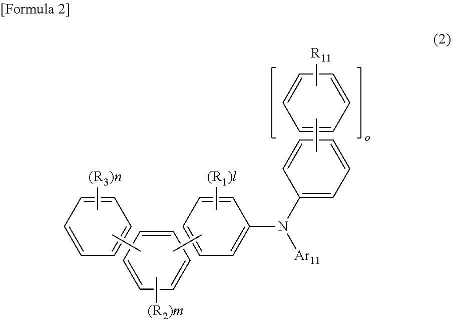

In the above Formula (2), R₁, R₂ and R₃ are independently a hydrogen atom, a halogen atom, a substituted or unsubstituted alkyl group having 1 to 15 carbon atoms, a substituted or unsubstituted aryl group having 6 to 30 carbon atoms, or a substituted or unsubstituted heteroaryl group having 1 to 30 carbon atoms, each of l, m and n is an integer satisfying 0≦l≦4, 0≦m≦4, and 0≦n≦5, Ar₁₁ is a substituted or unsubstituted aryl group having 6 to 30 carbon atoms, R₁₁ is a hydrogen atom, a fluorine atom, or a substituted silyl group, and o is an integer satisfying 0≦o≦3. When o is greater than or equal to 2, the R₁₁ s may be different from each other among the above-defined substituents.

Examples of the carbazole derivative that may form the hole transport layer B include, for example, compounds illustrated by the following Formula (3).

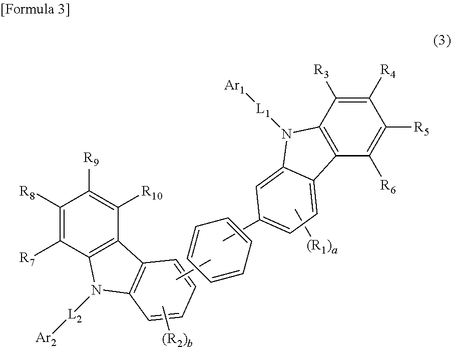

In the above Formula (3), Ar₁ is a substituted or unsubstituted aryl group having 6 to 30 carbon atoms, a substituted or unsubstituted heteroaryl group having 1 to 30 carbon atoms, or a substituted or unsubstituted alkyl group having 1 to 15 carbon atoms, R₁ to R₁₀ are independently a substituted or unsubstituted aryl group having 6 to 30 carbon atoms, a substituted or unsubstituted heteroaryl group having 1 to 30 carbon atoms, a substituted or unsubstituted alkyl group having 1 to 15 carbon atoms, a substituted or unsubstituted alkoxy group, a halogen atom, a hydrogen atom, or a deuterium atom. Ar₂ is a substituted or unsubstituted condensed ring having 6 to 30 carbon atoms and optionally including a heteroatom selected from the group of nitrogen, oxygen, sulfur, phosphorus, and silicon, or a substituted or unsubstituted condensed ring including carbon and nitrogen. Ar₁ and Ar₂ are different substituents from each other, a and b are 0 to 3, L₁ and L₂ are a single bond, or a divalent connecting group, and a plurality of adjacent R₁ to R₁₀ may combined and form an unsaturated ring (Here, R₁ and R₆, or R₂ and R₁₀ may be combined, and an aromatic ring is not formed).

Examples of the alkyl group having 1 to 15 carbon atoms may include a C1-C15 alkyl group having a chain shape or a ring shape such as a methyl group, an ethyl group, a propyl group, an isopropyl group, a cyclopropyl group, a butyl group, an isobutyl group, a tert-butyl group, a cyclobutyl group, a pentyl group, an isopentyl group, a neopentyl group, a cyclopentyl group, a hexyl group, a cyclohexyl group, a heptyl group, an octyl group, a nonyl group, and a decyl group.

The alkoxy group having 1 to 15 carbon atoms may be a functional group having a chemical formula of —OA, where, A is a substituted or unsubstituted C1-C15 alkyl group as described above). Particular examples of the C1-C15 alkoxy group may include a methoxy group, an ethoxy group, a propoxy group, etc.

The term “unsubstituted aryl group having 6 to 30 carbon atoms” may denote a monovalent group having a C6-C30 carbon ring including at least one aromatic ring. When the aryl group includes at least two rings, the rings may be fused to each other.

Particular examples of the substituted or unsubstituted C6-C30 aryl group may include a phenyl group, a pentalenyl group, an indenyl group, a naphthyl group, an anthracenyl group, an azulenyl group, a heptalenyl group, an acenaphthylenyl group, a phenalenyl group, a fluorenyl group, an anthraquinolyl group, a phenanthryl group, a biphenyl group, a triphenylenyl group, a pyrenyl group, a chrysenyl group, a picenyl group, a perylenyl group, a pentaphenyl group, a pentacenyl group, a tetraphenylene group, a hexaphenyl group, a hexacenyl group, a rubicenyl group, a trinaphthylenyl group, a heptaphenyl group, a pyranthrenyl group, etc.

The term “unsubstituted heteroaryl having 1 to 30 carbon atoms” may refer to a monovalent group having a ring including at least one aromatic ring that includes at least one hetero atom selected from N, O, P and S, with the remaining atoms being C. When the heteroaryl group includes at least two rings, the rings may be fused to each other.

Examples of the unsubstituted C1-C30 heteroaryl group include a pyrazolyl group, an imidazolyl group, an oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, a benzoimidazolyl group, an imidazopyridinyl group, an imidazopyrimidinyl group, etc.

The above-described hole transport materials may be purchased from commercially available materials or may be obtained by an optional synthetic method.

As described above, the configuration of the hole transport layer 108 according to an embodiment has been explained in detail.

### EXAMPLES

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

<Synthesis of Hole Transport Materials>

Hole transport materials used in the following embodiments were synthesized as follows.

[Synthesis of Hole Transport Material HTM1]

The following chemical reaction illustrates the synthetic processes of hole transport material HTM1.

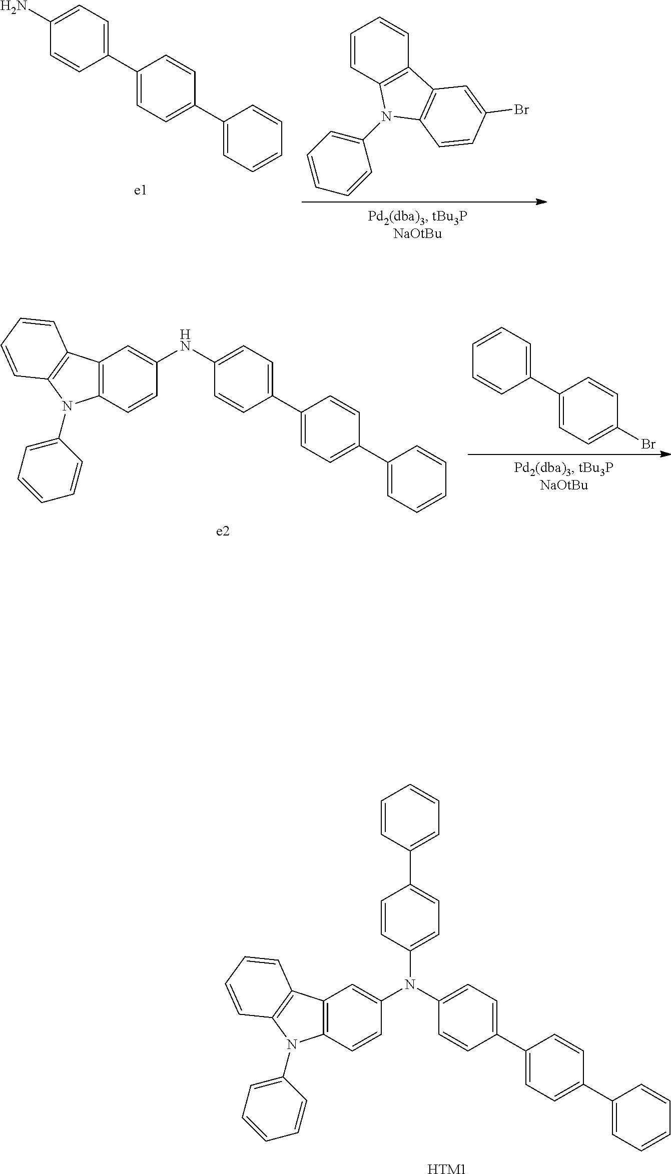

[Synthesis of Compound e2]

3.39 g of 4-terphenylamine (e1), 4.45 g of 3-bromo-9-phenylcarbazole, 0.715 g of tris(dibenzylideneacetone)dipalladium(O)·chloroform adduct, 3.98 g of sodium-t-butoxide, and 0.864 mL of tri-t-butylphosphine in a 1.6 M xylene solution were added to 500 mL of xylene, followed by degassing and heating at 120° C. for 12 hours under an argon atmosphere. After cooling, the reactant was poured into water and extracted with toluene. An organic layer was washed with water and saturated brine, dried with magnesium sulfate and concentrated. The residue thus obtained was separated by silica gel chromatography to obtain 5.58 g of carbazolylamine e2.

[Synthesis of Compound HTM1]

4.65 g of carbazolylamine e2, 2.67 g of 4-amino-p-biphenyl, 0.495 g of tris(dibenzylideneacetone)dipalladium(O)·chloroform adduct, 3.98 g of sodium-t-butoxide, and 0.597 mL of tri-t-butylphosphine in a 1.6 M xylene solution were added to 300 mL of xylene, followed by degassing and heating at 120° C. for 18 hours under an argon atmosphere. After cooling, the reactant was poured into water and extracted with toluene. An organic layer was washed with water and saturated brine, dried with magnesium sulfate and concentrated. The residue thus obtained was separated by a FLORISIL and silica gel short column to obtain 4.76 g of Compound HTM1.

[Synthesis of Hole Transport Material HTM2]

The following chemical reaction illustrates the synthetic processes of hole transport material HTM2.

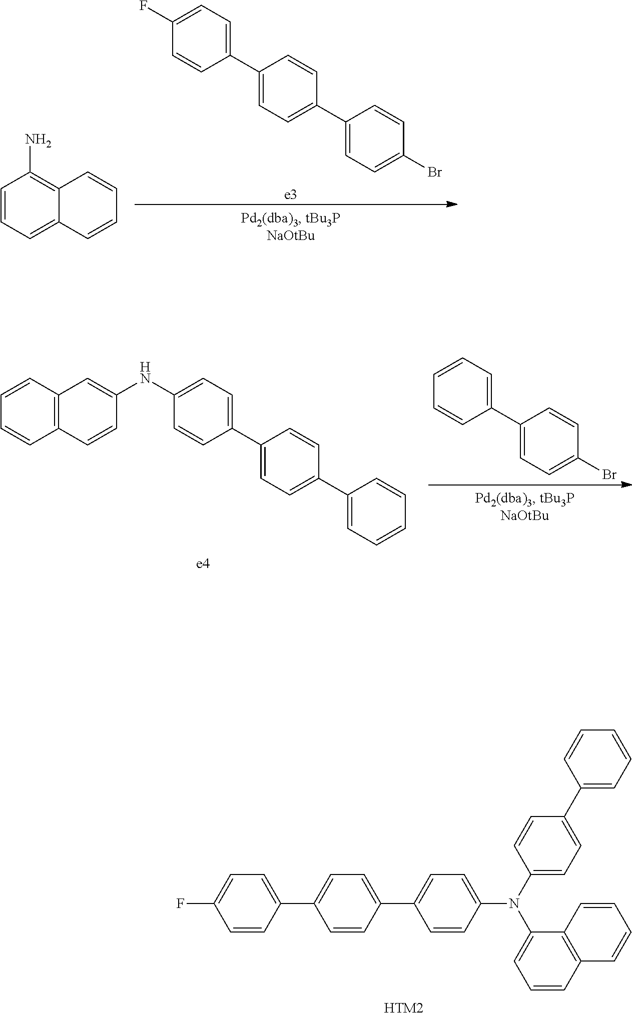

[Synthesis of Compound e4]

2.82 g of 1-naphthylamine, 6.45 g of bromofluoroterphenyl e3, 1.02 g of tris(dibenzylideneacetone)dipalladium(O)·chloroform adduct, 5.69 g of sodium-t-butoxide, and 1.23 mL of tri-t-butylphosphine in a 1.6 M xylene solution were added to 500 mL of xylene, followed by degassing and heating at 120° C. for 18 hours under an argon atmosphere. After cooling, the reactant was poured into water and extracted with toluene. An organic layer was washed with water and saturated brine, dried with magnesium sulfate and concentrated. The residue thus obtained was separated by silica gel chromatography to obtain 5.53 g of fluoroterphenylamine e4.

[Synthesis of Compound HTM2]

4.25 g of fluoroterphenylamine e4, 3.06 g of 4-amino-p-biphenyl, 0.565 g of tris(dibenzylideneacetone)dipalladium(O)·chloroform adduct, 3.15 g of sodium-t-butoxide, and 0.683 mL of tri-t-butylphosphine in a 1.6 M xylene solution were added to 300 mL of xylene, followed by degassing and heating at 120° C. for 24 hours under an argon atmosphere. After cooling, the reactant was poured into water and extracted with toluene. An organic layer was washed with water and saturated brine, dried with magnesium sulfate and concentrated. The residue thus obtained was separated by a FLORISIL and silica gel short column to obtain 3.85 g of Compound HTM2.

[Synthesis of Hole Transport Material HTM3]

The following chemical reaction illustrates the synthetic processes of hole transport material HTM3.

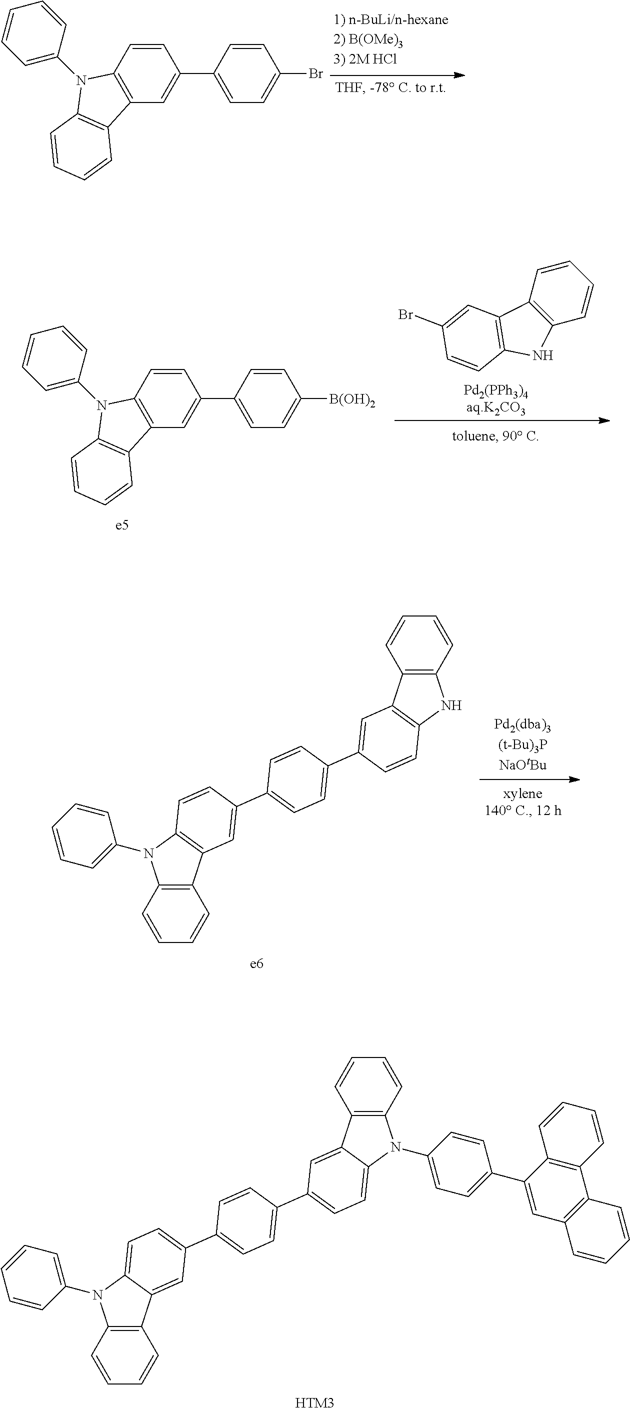

[Synthesis of Compound e5]

Under an argon atmosphere, 20.0 g of 3-(4-bromophenyl)-9-phenyl-9H-carbazole was inserted in a 1 L, four-necked flask, followed by stirring in 350 mL of THF at −78° C. for 5 minutes. 7.20 mL of 1.58 M n-butyl lithium (in n-hexane solution) was added thereto, followed by stirring at −78° C. for 1 hour. Then, 2.11 mL of trimethoxyborane was added thereto, followed by stirring at room temperature for 2 hours. 250 mL of a 2M aqueous hydrogen chloride solution was added thereto, followed by stirring at room temperature for 3 hours. An organic layer was separated, and solvents were distilled off. Then, the residue thus obtained was recrystallized using a solvent system of ethyl acetate and hexane to produce 15.69 g of Compound e5 as white solid (yield 85%).

[Synthesis of Compound e6]

Under an argon gas atmosphere, 14.0 g of Compound e5, 10.4 g of 3-bromocarbazole, 3.12 g of tetrakis(triphenylphosphine)palladium (Pd(PPh₃)₄), 10.7 g of potassium carbonate (K₂CO₃), 80 mL of water, and 30 mL of ethanol were added in a 1 L, four-necked flask, followed by stirring in 400 mL of a toluene solvent at 90° C. for 4 hours. After cooling in the air, an organic layer was separated, and solvents were distilled. Then, the residue thus obtained was recrystallized to produce 2.86 g of Compound A as white solid (yield 70%).

[Synthesis of Compound HTM3]

Under an argon gas atmosphere, 9.70 g of Compound e6, 6.76 g of 2-bromophenanthrene, 1.45 g of tris(dibenzylideneacetone)dipalladium(O) (Pd₂(dba)₃), 510 mg of tri-tert-butylphosphine ((t-Bu)₃P) and 5.77 g of sodium t-butoxide were added to a 500 mL, three-necked flask, followed by heating and stirring in 50 mL of a xylene solvent at 120° C. for 12 hours. After cooling in the air, water was added in the reactant, an organic layer was separated, and solvents were distilled. The crude product thus obtained was separated by silica gel column chromatography (using a mixture solvent of dichloromethane and hexane), and recrystallized using a mixture solvent of toluene and hexane to produce 10.7 g of Compound HTM3 as white solid (yield 75%).

In addition, HTM4 and HTM5 illustrated in the following structures were purchased from Lumtec Co.

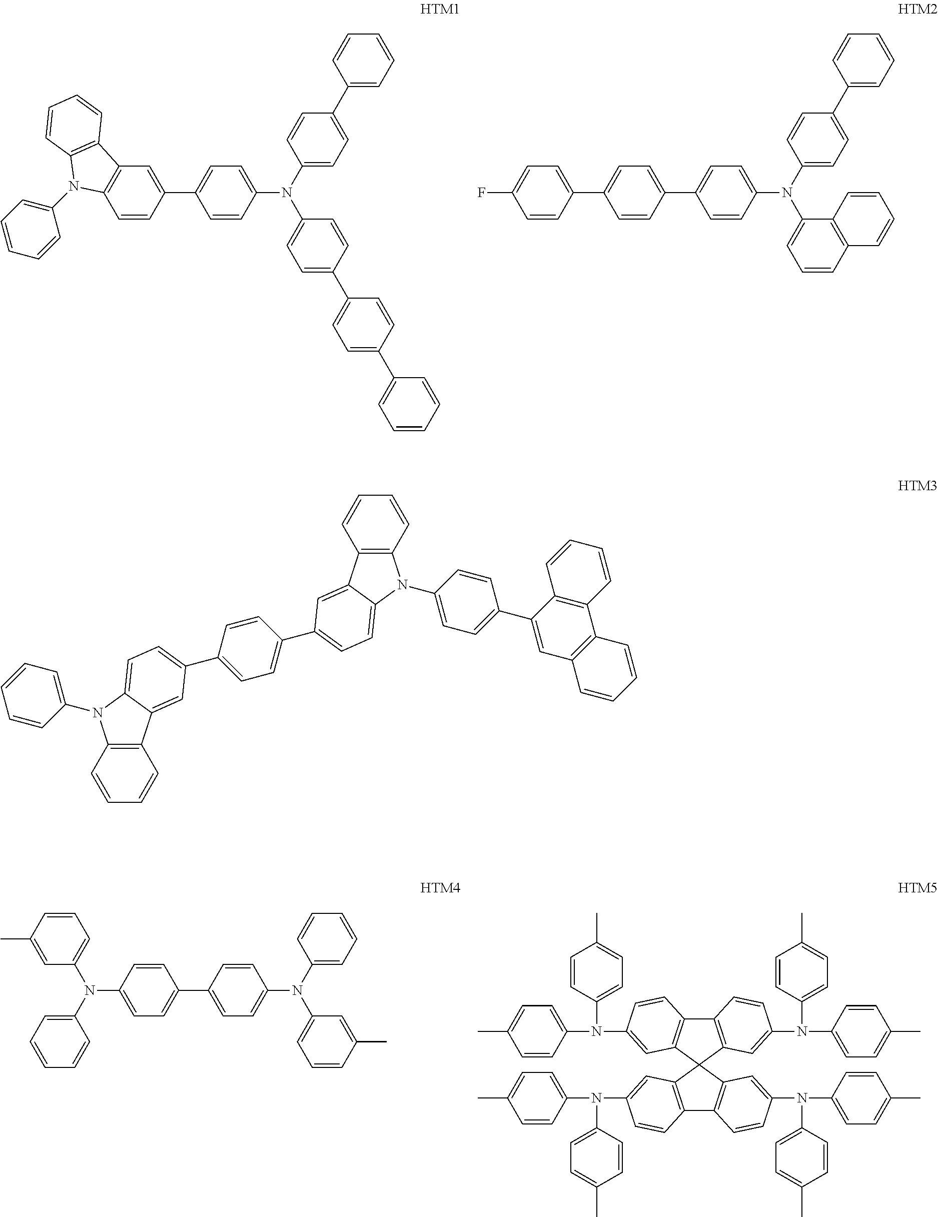

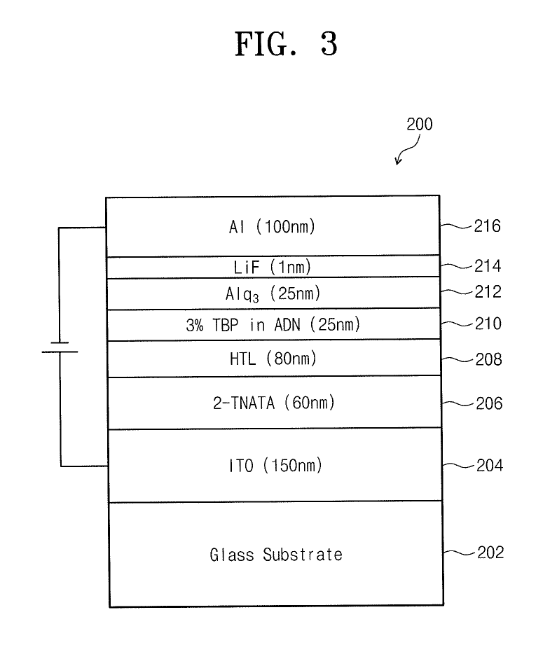

In the following examples and comparative examples, organic EL devices 200 having the entire configuration illustrated in FIG. 3 were manufactured, and the device performance of the organic EL devices thus manufactured was examined. The schematic diagram of the organic EL device 200 thus manufactured is illustrated in FIG. 3.

The organic EL device 200 thus manufactured included an anode 204, a hole injection layer 206 disposed on the anode 204, a hole transport layer 208 disposed on the hole injection layer 206, an emission layer 210 disposed on the hole transport layer 208, an electron transport layer 212 and an electron injection layer 214 disposed on the emission layer 210, and a cathode 216 disposed on the electron injection layer 214. Among the elements, the hole transport layer 208 was formed so as to include a plurality of layers using the materials illustrated in the following Table 1.

More particularly, the organic EL device according to an embodiment was manufactured by the following processes. First, with respect to an ITO glass substrate patterned and cleaned in advance, a surface treatment using ozone (O₃) was performed. The layer thickness of the ITO layer was about 150 nm. After the ozone treatment, the substrate was inserted in a vacuum deposition apparatus, a layer was formed using 2-TNATA as a hole injection material to a layer thickness of about 60 nm on the ITO layer at less than about 1×10⁻⁵ Pa.

Then, a hole transport layer HTL was formed using the above described Compounds HTM1 to HTM5 as hole transport materials as illustrated in Table 1 to an entire thickness of about 80 nm. After that, a layer was formed by co-depositing ADN doped with 3 vol % of TBPe as an emission material to a layer thickness of about 25 nm.

Subsequently, a layer was formed using Alq₃ as an electron transport material to a layer thickness of about 25 nm, and then, LiF as an electron injection material to a layer thickness of about 1.0 nm and aluminum as a cathode to a layer thickness of about 100 nm were stacked one by one. The substrate was taken out from the vacuum deposition apparatus into a glove box, and the substrate and glass were adjusted and attached in the glove box using an epoxy resin and encapsulated to manufacture an organic EL device 200.

[Measuring Mobility]

The substrate thus manufactured and pre-treated was inserted in a deposition apparatus, and a layer of a material for measuring mobility was formed to a thickness of about 3 μm and a layer was formed using Al to a thickness of about 100 nm as an electrode. After performing encapsulation, mobility was obtained from the moving speed of charges from the ITO transparent electrode to the Al electrode generated during exposure to a nitrogen laser by using a mobility measuring apparatus of OPTEL Co.

The thickness of the hole transport material used, and the emission efficiency, the driving voltage and the luminance half life of the organic EL device 200 thus manufactured were summarized and the values are shown in the following Table 1. For the evaluation of the properties of the organic EL devices 200 thus manufactured, a luminance system CS-2000 of KONICA MINOLTA Co. and a Source Meter 2400 of Keithley Co. were used.

In the following Table 1, the current efficiency (cd/A) and the driving voltage (V) are values at 2.5 mA/cm², and the luminance half life (hours) is the time period necessary for decreasing the luminance to half of initial luminance when driven at 1,000 cd/m². In addition, in the following Table 1, the values are relative values when the emission luminance, the driving voltage and the life of the organic EL device according to Example 1 were set 100.

TABLE 1

| | Hole transport layer | | | Current | | Luminance |
|---|---|---|---|---|---|---|
| | Hole transport | Hole transport | Hole transport | efficiency | Driving | half life |
| | layer A | layer B | layer C | (cd/A) | voltage (V) | (hours) |
| Example 1 | HTM2 (72 nm) | HTM1 (8 nm) | — | 100 | 100 | 100 |
| Example 2 | HTM2 (76 nm) | HTM1 (4 nm) | — | 100 | 100 | 110 |
| Example 3 | HTM2 (78 nm) | HTM1 (2 nm) | — | 100 | 100 | 110 |
| Example 4 | HTM2 (72 nm) | HTM3 (8 nm) | — | 100 | 100 | 110 |
| Example 5 | HTM4 (72 nm) | HTM1 (8 nm) | — | 100 | 90 | 90 |
| Example 6 | HTM5 (72 nm) | HTM1 (8 nm) | — | 100 | 110 | 90 |
| Example 7 | HTM2 (72 nm) | HTM1:HTM4 = | — | 90 | 100 | 100 |
| | | 8:2 (8 nm) | | | | |
| Example 8 | HTM2 (69 nm) | HTM1 (8 nm) | HTM3 (3 nm) | 100 | 100 | 100 |
| Example 9 | HTM2 (71 nm) | HTM1 (8 nm) | HTM2 (1 nm) | 100 | 100 | 100 |
| Comparative | HTM1 (72 nm) | HTM2 (8 nm) | — | 80 | 200 | 50 |
| Example 1 | | | | | | |
| Comparative | HTM3 (72 nm) | HTM2 (8 nm) | — | 80 | 250 | 40 |
| Example 2 | | | | | | |
| Comparative | HTM1 (72 nm) | HTM23(8 nm) | — | 40 | 500 | 10 |
| Example 3 | | | | | | |

In the case when samples for measuring hole mobility were manufactured using each of the hole transport materials, the hole mobility at 0.7 MV/cm was 6.8×10⁻⁴ cm²/V·sec for HTM1, 5.2×10⁻³ cm²/V·sec for HTM2, 1.3×10⁻⁵ cm²/V·sec for HTM3, 1.1×10⁻³ cm²/V·sec for HTM4, and 9.8×10⁻³ cm²/V·sec for HTM5. Among the samples for measuring the hole mobility, the hole mobility at 0.7 MV/cm was 2.0×10⁻⁴ cm²/V·sec for a sample including the hole transport layer obtained by co-depositing HTM1 and HTM4 in the ratio of 8:2.

Referring to the above Table 1, the organic EL devices of Examples 1 to 9 according to the embodiments showed higher efficiency and longer life when compared to those of Comparative Examples 1 to 3.

By way of summation and review, to improve the emission efficiency of an organic EL device, it is desirable to increase the probability of the recombination of holes and electrons in an emission layer. When either of the holes and the electrons is excessively supplied, charges may pass through the emission layer without recombination, and the emission efficiency of the emission layer may be deteriorated. Thus, the injection balance of the electrons and the holes is a factor in determining the emission efficiency and the life of the organic EL device.

To control the injection balance of the electrons and the holes as described above, the charge mobility of a plurality of layers making up an organic EL device may be controlled. For example, the hole mobility of a hole transport layer formed by only one layer in a predetermined range may be limited. However, in the case that the hole mobility of a hole transport layer formed by only one layer is controlled, the driving voltage of an organic EL device may be undesirably increased.

Embodiments advance the art by providing an organic EL device in which an increase of a driving voltage may be restrained while improving emission efficiency. The hole transport layer of the organic EL device may be formed so as to include a plurality of hole transport layers formed by using compounds having different hole mobility. Thus, the balance of the hole mobility may be maintained, the increase of a driving voltage may be restrained, and emission efficiency may be improved further. By delimiting the hole mobility of a first hole transport layer and at least one layer between a first hole transport layer and the emission layer in the hole transport layer, the balance of the hole mobility may be maintained, the increase of a driving voltage may be restrained, and emission efficiency may be improved further. By defining the thickness of at least one layer between a first hole transport layer and the emission layer in the hole transport layer, the increase of a driving voltage may be restrained, and emission efficiency may be improved further. By using one of three kinds of derivatives as the main component of the at least one layer between the first hole transport layer and the emission layer in the hole transport layer, the increase of a driving voltage may be restrained, and emission efficiency may be improved further. Overall, the increase of the driving voltage may be restrained, and the emission efficiency may be improved in an organic EL device by limiting the hole mobility of a first hole transport layer and at least one layer disposed in a hole transport layer between the first hole transport layer and an emission layer to a certain range

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. An organic electroluminescence (EL) device, comprising:
an anode;
a hole transport layer on the anode, the hole transport layer including a plurality of layers having different compounds as main components;
an emission layer on the hole transport layer; and
a cathode on the emission layer,
wherein a hole mobility of a first layer of the hole transport layer having the greatest thickness among the plurality of layers of the hole transport layer is greater than a hole mobility of at least one layer of the hole transport layer between the first layer of the hole transport layer and the emission layer.

2. The organic EL device as claimed in claim 1, wherein the hole mobility of the first layer of the hole transport layer in an electric field range from about 0.3 to about 1.0 MV/cm is from about 1×10⁻⁴ to about 1×10⁻³ cm²/V·sec and
the hole mobility of the at least one layer of the hole transport layer between the first layer of the hole transport layer and the emission layer in an electric field range from about 0.3 to about 1.0 MV/cm is from about 1×10⁻⁵to about 1×10⁻⁴ cm²/V·sec.

3. The organic EL device as claimed in claim 1, wherein a thickness of the at least one layer of the hole transport layer between the first layer of the hole transport layer and the emission layer is less than 1/10 of a thickness of the first hole transport layer.

4. The organic EL device as claimed in claim 1, wherein a main component of the at least one layer of the hole transport layer between the first layer of the hole transport layer and the emission layer is an aminocarbazole derivative.

5. The organic EL device as claimed in claim 4, wherein the aminocarbazole derivative is a compound represented by the following Formula (1a) or (1b): 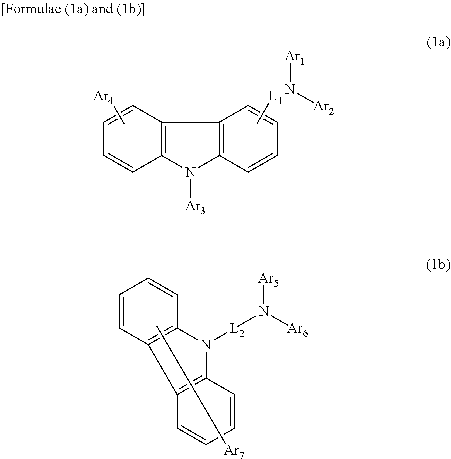
wherein, in Formula 1(a), Ar₁ to Ar₄ are a substituted or unsubstituted aryl group, or a substituted or unsubstituted heteroaryl group, and L₁ is a connecting group, a substituted or unsubstituted arylene group, or a substituted or unsubstituted heteroarylene group, and
in Formula 1(b), Ar₅ to Ar₇ are a substituted or unsubstituted aryl group, or a substituted or unsubstituted heteroaryl group, and L₂ is a connecting group, a substituted or unsubstituted arylene group, or a substituted or unsubstituted heteroarylene group.

6. The organic EL device as claimed in claim 1, wherein a main component of the at least one layer of the hole transport layer between the first layer of the hole transport layer and the emission layer is a monoamine derivative.

7. The organic EL device as claimed in claim 6, wherein the monoamine derivative is a compound represented by the following Formula (2): 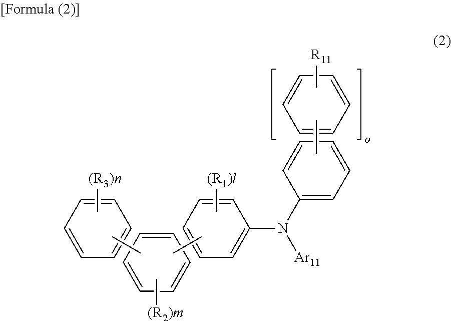
wherein, in Formula (2), R₁, R₂ and R₃ are independently a hydrogen atom, a halogen atom, a substituted or unsubstituted alkyl group having 1 to 15 carbon atoms, a substituted or unsubstituted aryl group having 6 to 30 carbon atoms, or a substituted or unsubstituted heteroaryl group having 1 to 30 carbon atoms,
each of l, m and n is an integer satisfying 0≦l≦4, 0≦m≦4, and 0≦n≦5,
Ar₁₁ is a substituted or unsubstituted aryl group having 6 to 30 carbon atoms,
R₁₁ is a hydrogen atom, a fluorine atom, or a substituted silyl group, and
o is an integer satisfying 0≦o≦3,
where in the case that o is greater than or equal to 2, R₁₁ may be different from each other among the above-described substituents.

8. The organic EL device as claimed in claim 1, wherein a main component of the at least one layer of the hole transport layer between the first layer of the hole transport layer and the emission layer is a carbazole derivative.

9. The organic EL device as claimed in claim 8, wherein the carbazole derivative is a compound represented by the following Formula (3): 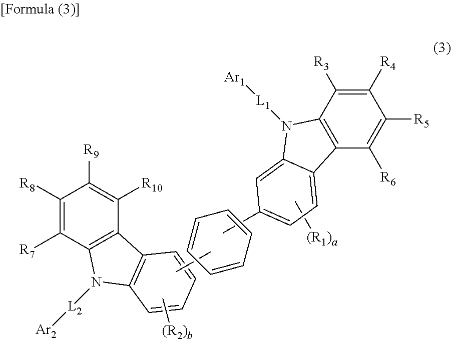
wherein, in Formula (3), Ar₁ is a substituted or unsubstituted aryl group having 6 to 30 carbon atoms, a substituted or unsubstituted heteroaryl group having 1 to 30 carbon atoms, or a substituted or unsubstituted alkyl group having 1 to 15 carbon atoms,
R₁ to R₁₀ are independently a substituted or unsubstituted aryl group having 6 to 30 carbon atoms, a substituted or unsubstituted heteroaryl group having 1 to 30 carbon atoms, a substituted or unsubstituted alkyl group having 1 to 15 carbon atoms, a substituted or unsubstituted alkoxy group, a halogen atom, a hydrogen atom, or a deuterium atom,
Ar₂ is a substituted or unsubstituted condensed ring having 6 to 30 carbon atoms and optionally including a heteroatom selected from the group of nitrogen, oxygen, sulfur, phosphorus and silicon, or a substituted or unsubstituted condensed ring including carbon and nitrogen,
Ar₁ and Ar₂ are different substituents from each other,
a and b are 0 to 3,
L₁ and L₂ are a single bond, or a divalent connecting group, and
a plurality of adjacent R₁ to R₁₀ may combine and form an unsaturated ring, where R₁ and R₆, or R₂ and R₁₀ are combined, and an aromatic ring is not formed.

10. The organic EL device as claimed in claim 1, wherein the emission layer includes a blue fluorescent emitting material.

11. The organic EL device as claimed in claim 1, wherein the emission layer includes a red phosphorescent emitting material.

12. The organic EL device as claimed in claim 1, wherein the emission layer includes a green phosphorescent emitting material.
